(19) United States
(12) Patent Application Publication
(10) Pub. No.: US 2022/0004792 A1
(43) Pub. Date: Jan. 6, 2022

(54) IMAGE SENSOR, PREPARATION METHOD THEREOF, IMAGE RECOGNITION METHOD, AND ELECTRONIC APPARATUS

(71) Applicant: Suzhou Mixosense Technology Ltd, Jiangsu (CN)

(72) Inventors: Di JIANG, Jiangsu (CN); Teng WANG, Jiangsu (CN); Dalong ZHANG, Jiangsu (CN)

(21) Appl. No.: 17/298,311

(22) PCT Filed: Nov. 29, 2019
(86) PCT No.: PCT/CN2019/122025

§ 371 Date: May 28, 2021

(30) Foreign Application Priority Data
Mar. 4, 2019 (CN) 201910160614.9

(51) Int. Cl. G06K 9/20; H04N 5/369; G06K 9/62; G06K 9/32; G06T 7/73; H01L 27/146

(52) U.S. Cl. CPC G06K 9/209; H04N 5/379; G06K 9/6215; G06K 9/3216; H01L 27/14683; H01L 27/14618; H01L 27/14636; H01L 27/14627; G06T 7/73

(57) ABSTRACT

Provided is an image sensor and a manufacturing method thereof, an image recognition method and an electronic device. The image sensor includes a sensor unit array, an encapsulation layer, a rewiring layer and a circuit board. The sensor unit array includes multiple sensor units, the multiple sensor units are arranged in an array, each sensor unit is configured to generate a respective partial size image of an imaging object, and each sensor unit includes at least one interconnection structure. The encapsulation layer wraps the sensor unit array, and exposes the interconnection structure of each sensor unit. The rewiring layer is disposed on a side of the encapsulation layer, and is electrically connected to the interconnection structure. The circuit board is disposed on a side of the rewiring layer away from the encapsulation layer, and is electrically connected to the rewiring layer.

### CROSS-REFERENCE TO RELATED APPLICATIONS

This is a National Stage Application filed under 35 U.S.C. 371 based on International Patent Application No. PCT/CN2019/122025, filed on Nov. 29, 2019, which claims priority to Chinese Patent Application No. 201910160614.9 filed Mar. 4, 2019, the disclosures of both of which are incorporated herein by reference in their entireties.

### TECHNICAL FIELD

Embodiments of the present application relate to the technical field of an image sensor, and for example, to an image sensor, a method for manufacturing the image sensor, an image recognition method, and an electronic device.

### BACKGROUND

An image sensor converts an optical image into an electrical signal. With the development of the computer and communication industries, there is an increasing need for high performance image sensors in various fields such as a digital camera, a video recorder, a personal communication system (PCS), a game console, a camera, and a medical micro-camera.

In the related art, the image sensor may include an image sensing chip and a lens covering the image sensing chip. An imaging object is imaged on the image sensing chip through the lens, and then the image sensing chip is controlled to be exposed through a control unit disposed on the periphery of the image sensing chip, such that an optical signal is converted into an electric signal, and thus an image of the imaging object is obtained.

However, the image sensor in the related art requires a large area of the image sensing chip, and the image sensing chip is expensive, resulting in the high cost of the image sensor.

### SUMMARY

Embodiments of the present application provide an image sensor, a method for manufacturing the image sensor, an image recognition method, and an electronic device, to avoid the high cost for manufacturing the image sensor in the related art.

In a first aspect, an embodiment of the present application provides an image sensor. The image sensor includes a sensor unit array, an encapsulation layer, a rewiring layer and a circuit board. The sensor unit array includes multiple sensor units, the multiple sensor units are arranged in an array, each of the multiple sensor units is configured to generate a respective partial size image of an imaging object, and each of the multiple sensor units includes at least one interconnection structure. The encapsulation layer wraps the sensor unit array, and exposes the at least one interconnection structure of each of the multiple sensor units. The rewiring layer is disposed on a side of the encapsulation layer, and is electrically connected to the at least one interconnection structure. The circuit board is disposed on a side of the rewiring layer away from the encapsulation layer, and is electrically connected to the rewiring layer.

In a second aspect, an embodiment of the present application further provides a method for manufacturing an image sensor. The method includes that: a base substrate is provided; a sensor unit array is formed on the base substrate, where the sensor unit array includes multiple sensor units, the multiple sensor units are arranged in an array, each of the multiple sensor units is configured to generate a respective partial size image of an imaging object, and each of the multiple sensor units includes at least one interconnection structure; an encapsulation layer is prepared on the base substrate, where the encapsulation layer wraps the sensor unit array, and exposes the at least one interconnection structure of each of the multiple sensor units; a rewiring layer is prepared on a side of the encapsulation layer away from the base substrate, where the rewiring layer is electrically connected to the at least one interconnection structure; and a circuit board is prepared on a side of the rewiring layer away from the encapsulation layer, where the circuit board is electrically connected to the rewiring layer.

In a third aspect, an embodiment of the present application further provides an image recognition method. The image recognition method adopts the image sensor provided in the first aspect. The method includes that: multiple partial size recognition images generated by the sensor unit array are acquired; position information of at least two image feature points is acquired based on the multiple partial size recognition images; and an image feature point recognition algorithm is adopted to recognize a recognition image captured by the image sensor according to the position information of the at least two image feature points.

In a fourth aspect, an embodiment of the present application further provides an electronic device. The electronic device includes the image sensor provided in the first aspect.

### BRIEF DESCRIPTION OF DRAWINGS

FIG. 1 is a schematic structural diagram of an image sensor according to an embodiment of the present application;

FIG. 2 is a schematic structural diagram of a sensor unit according to an embodiment of the present application;

FIG. 3 is a schematic structural diagram of another sensor unit according to an embodiment of the present application;

FIG. 4 is a schematic structural diagram of another sensor unit according to an embodiment of the present application;

FIG. 5 is a schematic structural diagram of another sensor unit according to an embodiment of the present application;

FIG. 6 is a schematic structural diagram of another sensor unit according to an embodiment of the present application;

FIG. 7 is a schematic structural diagram of another sensor unit according to an embodiment of the present application;

FIG. 8 is a schematic structural diagram of another sensor unit according to an embodiment of the present application;

FIG. 9 is a schematic structural diagram of another sensor unit according to an embodiment of the present application;

FIG. 10 is a schematic structural diagram of another sensor unit according to an embodiment of the present application;

FIG. 11 is a schematic diagram of an imaging principle of an image sensor according to an embodiment of the present application;

FIG. 12 is a schematic diagram of an image capturing principle of an image sensor according to an embodiment of the present application;

FIG. 13 is a schematic flowchart of an image recognition method according to an embodiment of the present application;

FIG. 14 is a schematic diagram of a principle of an image recognition method according to an embodiment of the present application;

FIG. 15 is a schematic diagram of an imaging principle of an image sensor to recognize a face image according to an embodiment of the present application;

FIG. 16 is a schematic diagram of an image capturing principle of an image sensor to recognize a face image according to an embodiment of the present application;

FIG. 17 is a schematic flowchart of a method for manufacturing an image sensor according to an embodiment of the present application; and

FIGS. 18 to 24 are each a schematic structural diagram illustrating a step of a method for manufacturing an image sensor according to an embodiment of the present application.

### DETAILED DESCRIPTION

Embodiments of the present application provide an image sensor. The image sensor includes a sensor unit array, an encapsulation layer, a rewiring layer and a circuit board. The sensor unit array includes multiple sensor units, the multiple sensor units are arranged in an array, each sensor unit is configured to generate a respective partial size image of an imaging object, and each sensor unit includes at least one interconnection structure. The encapsulation layer wraps the sensor unit array, and exposes the at least one interconnection structure of each sensor unit. The rewiring layer is disposed on a side of the encapsulation layer, and is electrically connected to the at least one interconnection structure. The circuit board is disposed on a side of the rewiring layer away from the encapsulation layer, and is electrically connected to the rewiring layer. By adopting the technical scheme described above, the image sensor includes the sensor unit array, the sensor unit array includes the multiple sensor units, the sensor includes the multiple sensor units arranged in the array, and each sensor unit generates the respective partial size image of the imaging object. Compared with a sensor chip disposed in a whole piece manner, the coverage area of the sensor chip can be saved, the total volume of a whole image sensor can be effectively reduced without affecting the imaging quality, the miniaturization design of the image sensor is easy to be implemented, and the manufacturing cost of the image sensor is saved. Meanwhile, each sensor unit includes at least one interconnection structure, the whole sensor unit array is connected to the rewiring layer and the circuit board through the interconnection structures, and the whole image sensor is encapsulated by adopting a fan-out process, so that a good encapsulation effect is ensured.

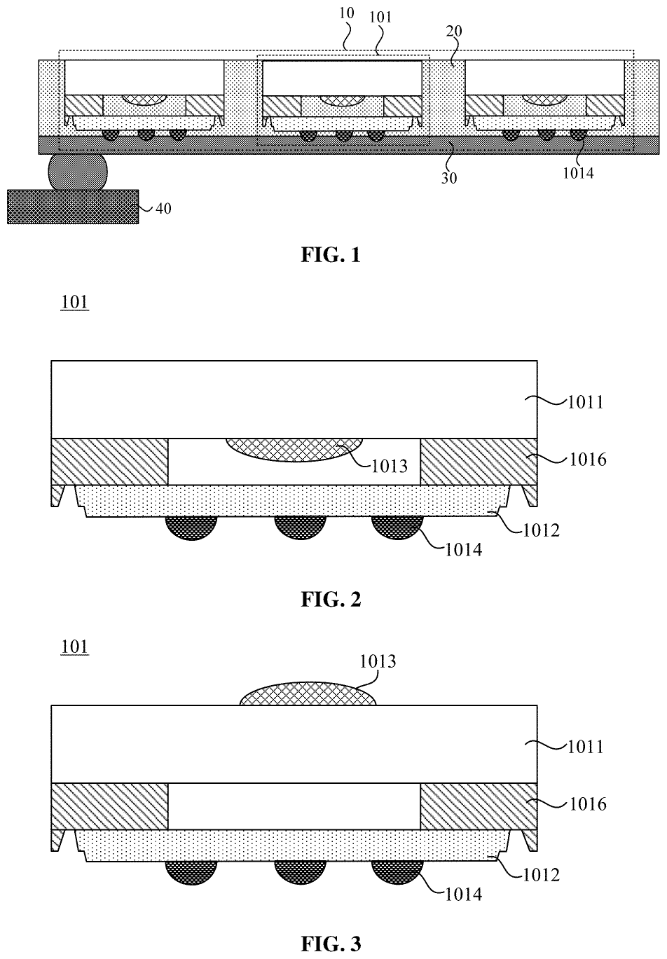

FIG. 1 is a schematic structural diagram of an image sensor according to an embodiment of the present application. As shown in FIG. 1, the image sensor provided in the embodiment of the present application may include a sensor unit array 10, an encapsulation layer 20, a rewiring layer 30 and a circuit board 40. The sensor unit array 10 includes multiple sensor units 101 arranged in an array, each sensor unit 101 is configured to generate a respective partial size image of an imaging object, and each sensor unit 101 includes at least one interconnection structure 1014. The encapsulation layer 20 wraps the sensor unit array 10, and exposes the interconnection structures 1014 of each sensor unit 101. The rewiring layer 30 is disposed on a side of the encapsulation layer 20, and the rewiring layer 30 is electrically connected to the interconnection structures 1014. The circuit board 40 is disposed on a side of the rewiring layer 30 away from the encapsulation layer 20, and is electrically connected to the rewiring layer 30.

As shown in FIG. 1, the image sensor provided in the embodiment of the present application may include the sensor unit array 10, the multiple sensor units 101 in the sensor unit array 10 are arranged in the array, and each sensor unit 101 generates the respective partial size image of the imaging object. Compared with a sensor chip arranged in a full-surface manner in the image sensor in the related art, the embodiment of the present application creatively applies a concept of “breaking up the whole into parts” to the image sensor, an image sensing chip designed in the full-surface manner in the related art is designed into the sensor unit array 10, the sensor unit array 10 includes multiple independently arranged sensor units 101, and each sensor unit 101 generates the respective partial size image of the imaging object. Compared with a full-surface image sensing chip, the technical scheme of the embodiment of the present application may reduce the coverage area of the image sensing chip and save the manufacturing cost of the image sensor.

Referring to FIG. 1, in the image sensor provided in the embodiment of the present application, each sensor unit 101 includes at least one interconnection structure 1014, each interconnection structure 1014 is electrically connected to the rewiring layer 30, the rewiring layer 30 is connected to the circuit board 40, and an electrical connection relationship between the sensor units 101 and the circuit board is implemented through the interconnection structures 1014 and the rewiring layer 30. The image sensor in the embodiment of the present application is encapsulated by using a fan-out process. Therefore, compared with a mode in which the sensor units 101 are directly connected to the circuit board 40 through wires, more sensor units 101 can be integrated in the image sensor, so that the integration flexibility is good, and a good encapsulation effect of the image sensor can be ensured.

In summary, according to the image sensor provided in the embodiment of the present application, the sensor includes multiple sensor units arranged in the array, and each sensor unit generates the respective partial size image of the imaging object. Compared with a sensor chip arranged in a whole piece manner, the coverage area of the sensor chip can be saved, the total volume of the whole image sensor can be effectively reduced without affecting the imaging quality, the miniaturization design of the image sensor is easy to be implemented, and the manufacturing cost of the image sensor is saved. Meanwhile, each sensor unit includes at least one interconnection structure, the whole sensor unit array is connected to the circuit board through the rewiring layer, and the whole image sensor is encapsulated by adopting a fan-out process, so that the good encapsulation effect is ensured.

FIG. 2 is a schematic structural diagram of a sensor unit according to an embodiment of the present application. As shown in FIG. 2, the sensor unit 101 provided in the embodiment of the present application may further include an encapsulation cover plate 1011, a sensor chip 1012 and at least one optical element 1013. The sensor chip 1012 is disposed on a side of the encapsulation cover plate 1011. The sensor chip 1012 is configured to generate the partial size image of the imaging object. The at least one optical element 1013 is disposed on a photosensitive side of the sensor chip 1012, and the optical element 1013 is configured to receive part of incident light of the imaging object and image the part of the incident light on the sensor chip 1012.

Exemplarily, the encapsulation cover plate 1011 may be a flexible substrate, and the material thereof may include at least one of polyimide, polyethylene terephthalate, polyethylene naphthalate, polycarbonate, polyarylate, or polyether sulfone. Alternatively, the encapsulation cover plate 1011 may be a rigid substrate, such as a silicon wafer, a glass substrate, or another rigid substrate. The type and material of the substrate are not limited in the embodiment of the present application.

The optical element 1013 is disposed corresponding to each sensor chip 1012. When the image sensor is in operation, the optical element 1013 receives the part of incident light of the imaging object and images the part of incident light on the sensor chip 1012 corresponding to the optical element 1013, and the sensor chip 1012 generates the partial size image of the imaging object.

A lens is used as an example. According to an imaging principle of an optical lens, 1/f=1/u+1/v, where f denotes a focal distance of the lens, u denotes an image distance, and v denotes an object distance. By adjusting the focal distance f of the lens and the distance v from the lens to an object to be imaged, the distance u between the optical element 1013 and the sensor chip 1012 may be adjusted, so that the area of the image is less than the area of the object by a certain multiple, and the size of the sensor chip 1012 is controlled, which provides a degree of freedom for the design of the sensor chip 1012 and ensures the flexibility of setting the size of each sensor chip 1012.

In an embodiment, the optical element 1013 may be disposed between a film layer where the encapsulation cover plate 1011 is located and a film layer where the sensor chip 1012 is located, as shown in FIG. 2; or, the optical element 1013 may be disposed on a side of the encapsulation cover plate 1011 away from the sensor chip 1012, as shown in FIG. 3, which is not limited in the embodiments of the present application.

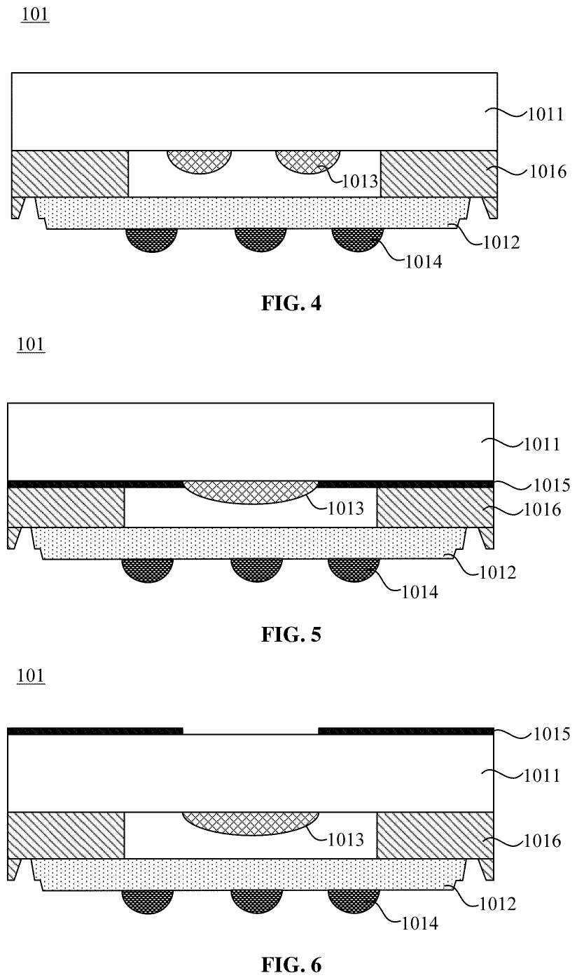

In an embodiment, each sensor chip 1012 may correspond to at least one optical element 1013. FIG. 2 illustrates an example in which each sensor chip 1012 may correspond to one optical element 1013, and FIG. 4 illustrates an example in which each sensor chip 1012 may correspond to two optical elements 1013, which is not limited in the embodiments of the present application.

In an embodiment, the interconnection structure 1014 may include at least one of a metal solder ball, a metal pad or a metal bump, which is not limited in the embodiments of the present application. The interconnection structure 1014 only needs to satisfy electrical and mechanical connection functions, and the drawings in the embodiments of the present application are illustrated by only using an example in which the interconnection structure 1014 is the metal solder ball.

FIGS. 5, 6, and 7 are each a schematic structural diagram of another display panel according to an embodiment of the present application. As shown in FIGS. 5, 6, and 7, the sensor unit provided in the embodiments of the present application may further include a coating 1015 disposed on each of at least one side surface of the encapsulation cover plate 1011, and an opening is formed in the coating 1015. An overlapping area exists between a vertical projection of the opening on a plane where the encapsulation cover plate 1011 is located and a vertical projection of the optical element 1013 on the plane where the encapsulation cover plate 1011 is located.

Exemplarily, FIG. 5 is illustrated by using an example in which the coating 1015 is disposed on a side of the encapsulation cover plate 1011 facing towards the sensor chip 1012, FIG. 6 is illustrated by using an example in which the coating 1015 is disposed on a side of the encapsulation cover plate 1011 away from the sensor chip 1012, and FIG. 7 is illustrated by using an example in which the coating 1015 is disposed on two side surfaces of the encapsulation cover plate 1011 separately. As shown in FIGS. 5, 6 and 7, the coating 1015 is disposed on at least the side surface of the encapsulation cover plate 1011, the opening is formed in the coating 1015, and the overlapping area exists between the vertical projection of the opening on the plane where the encapsulation cover plate 1011 is located and the vertical projection of the optical element 1013 on the plane where the encapsulation cover plate 1011 is located. Thus, it is ensured that a specific aperture is formed through the coating 1015 and the opening in the coating 1015, and light emitted by the imaging object reaches the optical element 1013 through the specific aperture. Therefore, it is ensured that the interference light can be filtered out, and the image quality of the image sensor can be enhanced.

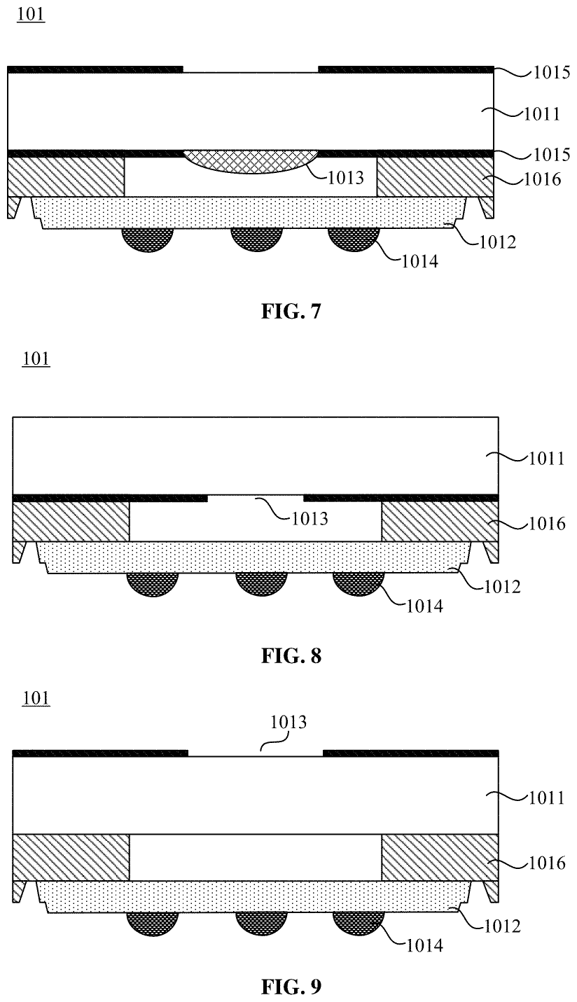

In an embodiment, in the sensor chip 101 provided in the embodiments of the present application, the optical element 1013 may be at least one of a lens, an imaging aperture or a collimator. FIGS. 1 to 7 are illustrated by using an example in which the optical element 1013 is the lens, and FIGS. 8 and 9 are illustrated by using an example in which the optical element 1013 is the imaging aperture.

In an embodiment, referring to FIGS. 2 to 9, the sensor unit 101 provided in the embodiments of the present application may further include a shim 1016, and the shim 1016 is disposed between the film layer where the encapsulation cover plate 1011 is located and a film layer where the sensor chip 1012 is located. Exemplarily, the shim 1016 is disposed between the encapsulation cover plate 1011 and the sensor chip 1012, and a distance between the optical element 1013 and the sensor chip 1012 may be adjusted by adjusting the thickness of the shim 1016, namely, the adjustment of the image distance is implemented. Thus, it is ensured that the sensor unit 101 provided in the embodiments of the present application is a sensor unit 101 with an adjustable image distance, and the flexibility and diversity of functions of the sensor unit are ensured.

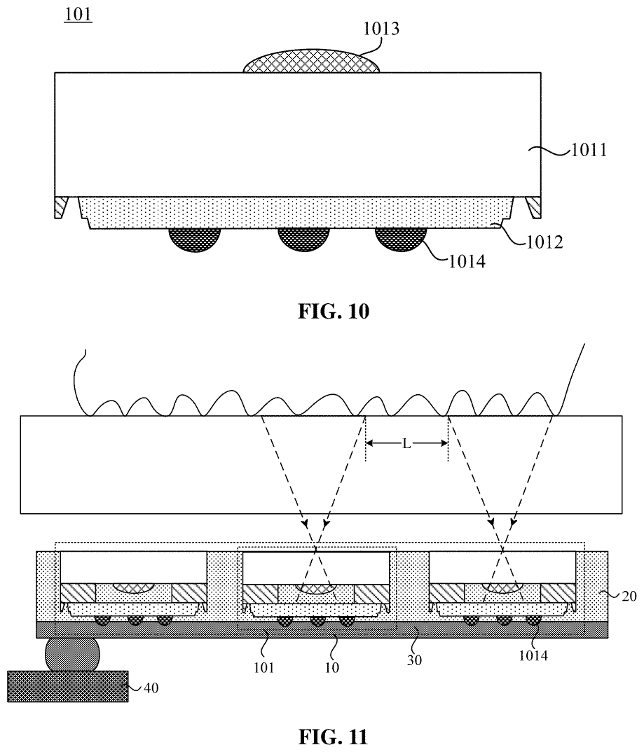

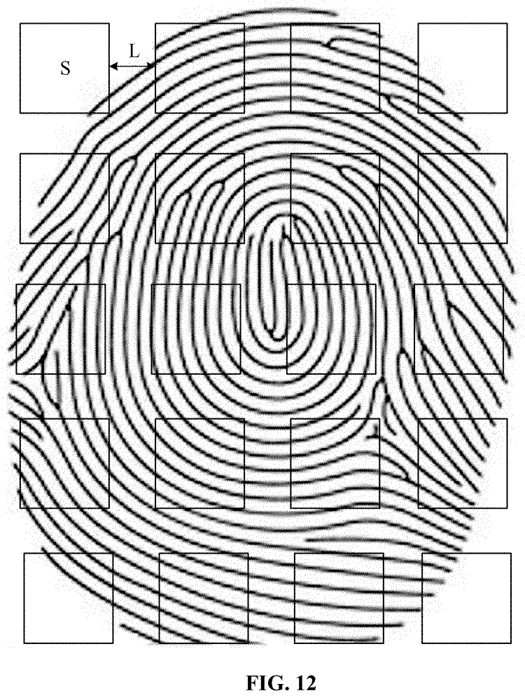

FIG. 10 is a schematic structural diagram of another sensor unit according to an embodiment of the present application. As shown in FIG. 10, in the case where the optical element 1013 is disposed on a side of the encapsulation cover plate 1011 away from the sensor chip 1012, the sensor unit 101 provided in the embodiment of the present application may not include the shim 1016. The distance between the optical element 1013 and the sensor chip 1012 may be adjusted by adjusting the thickness of the encapsulation cover plate 1011, namely, the adjustment of the image distance is implemented. Thus, it can be ensured that the sensor unit 101 provided in the embodiment of the present application is the sensor unit 101 with the adjustable image distance, and meanwhile it can be ensured that the sensor unit 101 is simple in structure.

In an embodiment, the image sensor provided in the embodiment of the present application includes the sensor unit array 10, the sensor unit array 10 includes multiple sensor units 101, each sensor unit 101 generates a respective partial size image of an imaging object, and the whole sensor unit array 10 may generate a complete size image of the imaging object or the partial size images of the imaging object, which is not limited in the embodiment of the present application. When the image recognition is performed, in the case where the sensor unit array 10 generates the complete size image of the imaging object, the complete size image of the imaging object generated by the sensor unit array 10 is compared with a preset image of the imaging object, and then the image recognition may be performed, which is not detailed in the embodiment of the present application. The embodiment of the present application focuses on describing how to perform the image recognition in the case where the sensor unit array 10 generates the partial size images of the imaging object below.

FIG. 11 is a schematic diagram of an imaging principle of an image sensor according to an embodiment of the present application. FIG. 12 is a schematic diagram of an image capturing principle of an image sensor according to an embodiment of the present application. As shown in FIGS. 11 and 12, the sensor unit 101 is configured to, based on incident light of the imaging object, form a coverage area S for the imaging object, and a distance between coverage areas S of two adjacent sensor units is L, where L >0.

Exemplarily, in the case where the distance L between the coverage areas S of two adjacent sensor units 101 is greater than 0, i.e. L >0, it is indicated that an effective visual angle of the sensor unit array 10 provided in the embodiment of the present application cannot completely cover the imaging object, and the sensor unit array 10 does not acquire a complete size image of the imaging object, so that the image recognition cannot be performed through a conventional image recognition method. Based on this, the embodiment of the present application creatively provides an image recognition method adopting “image feature point recognition”.

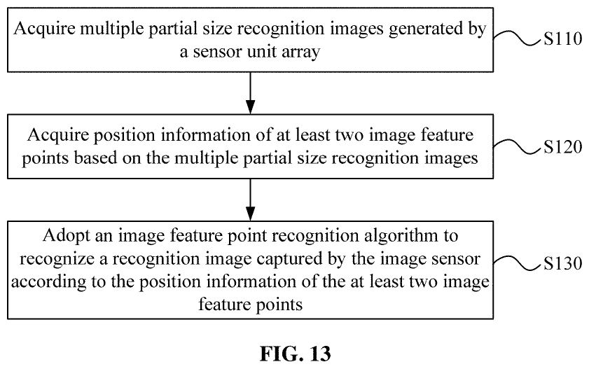

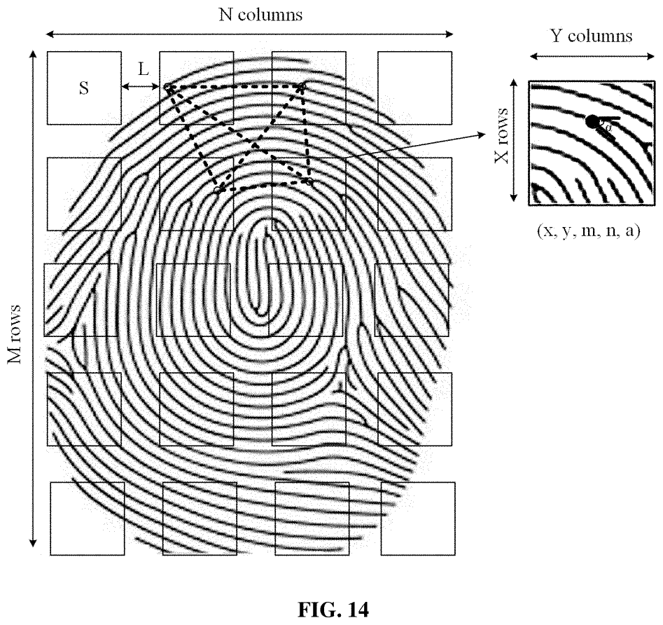

FIG. 13 is a schematic flowchart of an image recognition method according to an embodiment of the present application. FIG. 14 is a schematic diagram of a principle of an image recognition method according to an embodiment of the present application. As shown in FIGS. 13 and 14, the image recognition method provided in the embodiment of the present application may include steps S110 to S130.

In step S110, multiple partial size recognition images generated by a sensor unit array are acquired.

Exemplarily, multiple partial size recognition images generated by the sensor unit array are acquired first, and this step is completed through the capturing of the image sensor provided in the embodiment of the present application.

In step S120, position information of at least two image feature points is acquired based on the multiple partial size recognition images.

Exemplarily, as shown in FIG. 14, the recognition image finally captured by the image sensor is an array composed of multiple partial size recognition images, each partial size recognition image includes, with some probability, a feature point on the recognition image that may be used for recognition, such as black dots in FIG. 14.

Since each sensor unit array may include M rows and N columns of sensor units, each sensor unit may include X rows and Y columns of pixels. Thus, an image feature point falling within a coverage range of the sensor unit may be represented by a coordinate (x, y, m, n, a) located in a feature space. Here, x denotes an abscissa of the image feature point in a certain sensor unit, and 0≤x≤X; y denotes an ordinate of the image feature point in a certain sensor unit, and 0≤y≤Y; m denotes an abscissa of the sensor unit where the image feature point is located in the whole sensor unit array, and 0≤m≤M; n denotes an ordinate of the sensor unit where the image feature point is located in the whole sensor unit array, and 0≤n≤N; and a denotes a feature angle of the image feature point. FIG. 14 is illustrated by using an example in which a fingerprint cross point is used as the image feature point, and an included angle at a position of the fingerprint cross point is used as the feature angle of the image feature point.

Since the position of each sensor unit in the whole sensor unit array is known, a set of all image feature points located within the coverage ranges of the sensor units may be determined and acquired.

In step S130, an image feature point recognition algorithm is adopted to recognize a recognition image captured by the image sensor according to the position information of the at least two image feature points.

Exemplarily, the image feature point recognition algorithm is adopted to recognize the recognition image captured by the image sensor according to the acquired position information of the at least two image feature points.

The image feature point recognition algorithm may adopt the image feature point recognition algorithm known in the art. For example, the image feature point recognition algorithm may refer to a document “Direct gray-scale minutiae detection in fingerprints” with doi: 10.1109/34.566808, a document “Pores and ridges High-resolution fingerprint matching using level 3 features” with doi: 10.1109/TPAMI.2007.250596, a document “Fingerprint minutiae extraction from skeletonized binary images” with doi: 10.1016/S0031-3203(98)00107-1, and a document “Extraction of high confidence minutiae points from fingerprint images” with doi: 10.1109/ICCACS.2015.7361357.

According to the image recognition method provided in the embodiment of the present application, based on the recognition image captured by the image sensor provided in the embodiment of the present application, multiple partial size recognition images generated by the sensor unit array are acquired, the position information of the at least two image feature points is acquired based on the multiple partial size recognition images, and the image feature point recognition algorithm is adopted to recognize the recognition image captured by the image sensor according to the position information of the at least two image feature points. Since the recognition image captured by the image sensor cannot include all recognition image information, the image recognition method of “image feature point recognition” is creatively adopted in the embodiment of the present application. Therefore, it is ensured that the image recognition method is accurate and feasible, and that according to the image recognition method provided in the embodiment of the present application, the recognition image captured by the image sensor provided in the embodiment of the present application can be accurately recognized.

In an embodiment, the step in which the image feature point recognition algorithm is adopted to recognize the recognition image captured by the image sensor according to the position information of the at least two image feature points may include that: a distance between any two image feature points is calculated according to the position information of the at least two image feature points; and the image feature point recognition algorithm is adopted to recognize the recognition image captured by the image sensor according to the distance between any two image feature points.

Exemplarily, referring to FIG. 14, since the position of each sensor unit in the whole sensor unit array is known, the set of all image feature points located within the coverage ranges of the sensor units may be determined and acquired, and a distance between every two image feature points in the set may be accurately calculated. Coordinates of members in the whole image feature point set have uniqueness and certainty, and may be utilized by an image recognition algorithm based on image feature points, so that an image recognition function is implemented.

In an embodiment, before the multiple partial size recognition images generated by the sensor unit array are acquired, the method may further include that: multiple partial size entry images generated by the sensor unit array are acquired multiple times, and a partial size entry image library is generated; and an image stitching algorithm is adopted to generate a complete size entry image according to the partial size entry image library.

Exemplarily, the image recognition may generally be divided into two processes, i.e., image entry and image recognition. In the image entry, the system may require the entered object to move multiple times on an image entry plane of the image sensor, multiple partial size entry images generated by the sensor unit array are acquired multiple times, and the partial size entry image library is generated. Then, according to the partial size entry image library, the image stitching algorithm is adopted to cut and stitch the partial size entry images, and the complete entry image containing all image feature point information is generated. In a subsequent image recognition process, the acquired recognition image containing part of the image feature points is compared with the entry image containing all the image feature points to perform the image recognition.

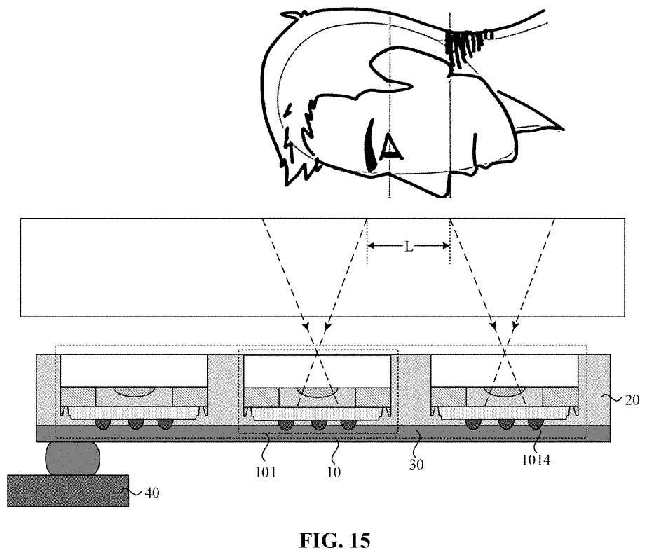

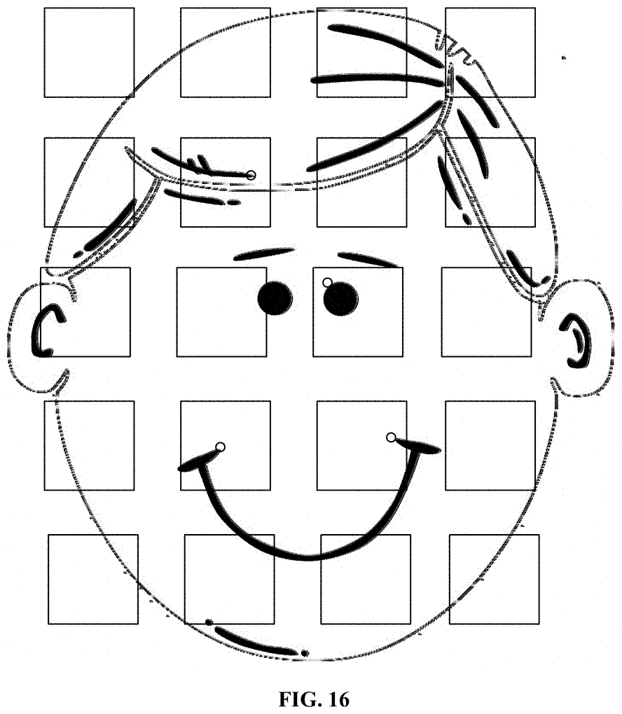

It is to be noted that the image recognition method provided in the embodiment of the present application is only explained by taking fingerprint recognition as an example. It can be understood that since the image distance of the sensor unit and the focal distance of the optical element in the image sensor provided in the embodiment of the present application are adjustable, the object distance of the sensor unit in the embodiment of the present application is also adjustable. Therefore, the image sensor provided in the embodiment of the present application may recognize objects with different object distances, for example, the image sensor provided in the embodiment of the present application may implement face recognition in combination with a face recognition algorithm, as shown in FIGS. 15 and 16.

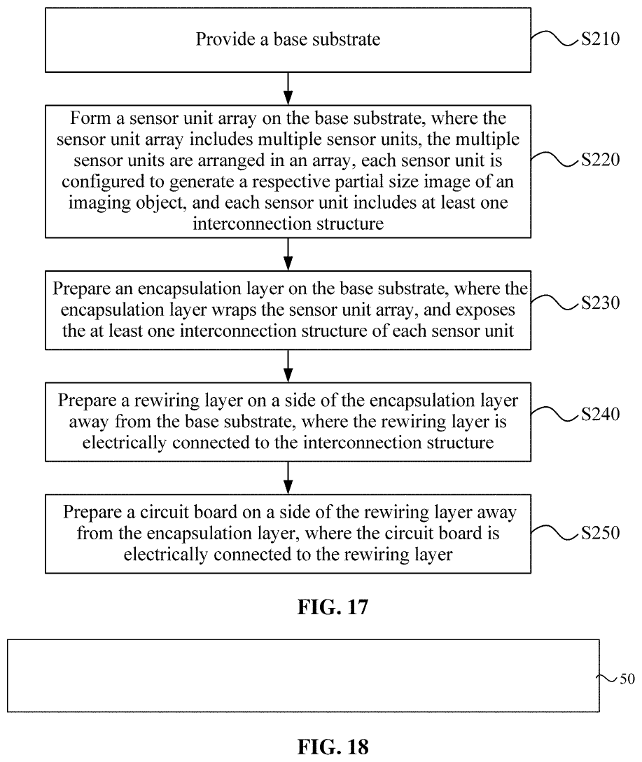

An embodiment of the present application further provides a method for manufacturing an image sensor. As shown in FIG. 17, the method for manufacturing the image sensor provided in the embodiment of the present application may include steps S210 to S250.

In step S210, a base substrate is provided.

FIG. 18 is a schematic structural diagram illustrating the preparation of a base substrate according to an embodiment of the present application. As shown in FIG. 18, the base substrate 50 may be a flexible substrate or a rigid substrate, and the type and material of the base substrate 50 are not limited in the embodiment of the present application.

In step S220, a sensor unit array is formed on the base substrate, where the sensor unit array includes multiple sensor units, the multiple sensor units are arranged in an array, each sensor unit is configured to generate a respective partial size image of an imaging object, and each sensor unit includes at least one interconnection structure.

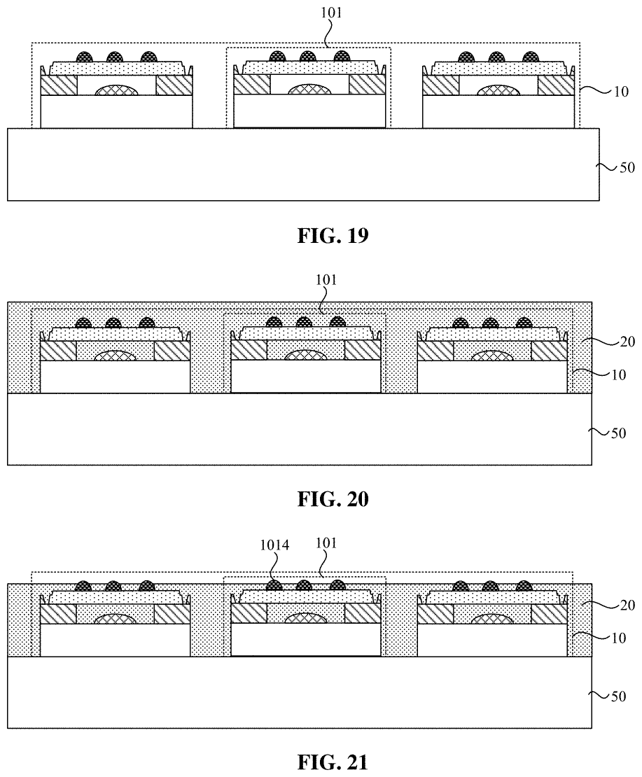

FIG. 19 is a schematic structural diagram illustrating that a sensor unit array 10 is formed on a base substrate according to an embodiment of the present application. As shown in FIG. 19, multiple sensor units 101 are arranged in the array on the base substrate 50 to form the sensor unit array 10.

In an embodiment, the sensor unit array 10 may be glued to the base substrate 50 by glue.

In an embodiment, a material of the interconnection structure 1014 may be solder metal, such as Sn, Ag, Cu, Pb, Au, Ni, Zn, Mo, Ta, Bi or In, and alloys thereof.

In step S230, an encapsulation layer is prepared on the base substrate, where the encapsulation layer wraps the sensor unit array, and exposes the at least one interconnection structure of each sensor unit.

Exemplarily, the step in which the encapsulation layer wrapping the sensor unit array and exposing the at least one interconnection structure of each sensor unit is prepared on the base substrate may include that: the encapsulation layer wrapping the sensor unit array is prepared on the base substrate; and the encapsulation layer is thinned to expose the at least one interconnection structure of each sensor unit.

FIG. 20 is a schematic structural diagram illustrating the preparation of an encapsulation layer according to an embodiment of the present application, and FIG. 21 is a structural schematic diagram illustrating the thinning of the encapsulation layer according to an embodiment of the present application. As shown in FIGS. 20 and 21, the encapsulation layer 20 is prepared on the base substrate 50 first, thereby ensuring that the encapsulation layer 20 completely wraps the sensor unit array 10, and then the encapsulation layer 20 is thinned to expose the interconnection structures 1014 of each sensor unit 101 for subsequent operations.

In step S240, a rewiring layer is prepared on a side of the encapsulation layer away from the base substrate, where the rewiring layer is electrically connected to the interconnection structures.

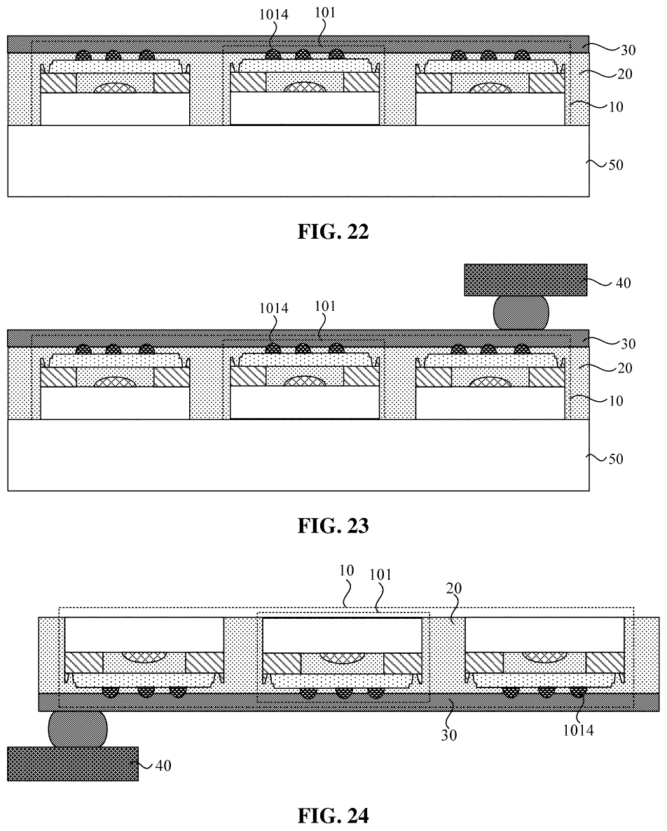

FIG. 22 is a schematic structural diagram illustrating the preparation of a rewiring layer according to an embodiment of the present application. As shown in FIG. 22, the preparation of the rewiring layer 20 may include a series of processes such as thin film deposition, electroplating, photolithography, development, and etching. A material of the rewiring layer 20 may be a metal material such as Al, Au, Cr, Ni, Cu, Mo, Ti, Ta, Ni-Cr or W, and alloys thereof.

In step S250, a circuit board is prepared on a side of the rewiring layer away from the encapsulation layer, where the circuit board is electrically connected to the rewiring layer.

FIG. 23 is a schematic structural diagram illustrating the preparation of a circuit board according to an embodiment of the present application. As shown in FIG. 23, the circuit board 40 is prepared on the side of the rewiring layer 30 away from the encapsulation layer 20, so that an electrical connection between the sensor units 101 and the circuit board 40 is achieved.

In summary, according to the method for manufacturing the image sensor provided in the embodiment of the present application, the sensor includes multiple sensor units arranged in the array, and each sensor unit generates the respective partial size image of the imaging object. Compared with a sensor chip disposed in a whole piece manner, the coverage area of the sensor chip can be saved, the total volume of the whole image sensor can be effectively reduced without affecting the imaging quality, the miniaturization design of the image sensor is easy to be implemented, and the manufacturing cost of the image sensor can be saved. Meanwhile, each sensor unit includes at least one interconnection structure, the whole sensor unit array is connected to the circuit board through the rewiring layer, the whole image sensor is encapsulated by adopting a fan-out process, so that a good encapsulation effect is ensured.

In an embodiment, the method for manufacturing the image sensor provided in the embodiment of the present application may further include that: the base substrate is stripped.

Exemplarily, FIG. 24 is a schematic structural diagram of a final image sensor obtained after the base substrate 50 is stripped according to an embodiment of the present application. The base substrate 50 is configured to carry a sensor chip array 10 to prepare the rewiring layer 30 and the circuit board 40 in subsequent processes, and after the rewiring layer 30 and the circuit board 40 are completed, the base substrate 10 may be stripped, thus ensuring a thinned design of the image sensor.

An embodiment of the present application further provides an electronic device, and the electronic device may include the image sensor provided in the embodiments of the present application, which is not repeated herein. In an embodiment, the electronic setting device provided in the embodiment of the present application may be a camera, a video camera, an attendance machine, a lens module, or other electronic device needing to use an image sensor, and the embodiments of the present application do not list them one by one.

1. An image sensor, comprising:
a sensor unit array, which comprises a plurality of sensor units, wherein the plurality of sensor units are arranged in an array, each of the plurality of sensor units is configured to generate a respective partial size image of an imaging object, and each of the plurality of sensor units comprises at least one interconnection structure;
an encapsulation layer, which wraps the sensor unit array, and exposes the at least one interconnection structure of each of the plurality of sensor units;
a rewiring layer, which is disposed on a side of the encapsulation layer, and is electrically connected to the at least one interconnection structure; and
a circuit board, which is disposed on a side of the rewiring layer away from the encapsulation layer, and is electrically connected to the rewiring layer.

2. The image sensor of claim 1, wherein each of the plurality of sensor units is configured to, based on incident light of the imaging object, form a respective coverage area for the imaging object; and
wherein a distance between coverage areas of every two adjacent sensor units of the plurality of sensor units is L, and L >0.

3. The image sensor of claim 1, wherein each of the plurality of sensor units further comprises:
an encapsulation cover plate;
a sensor chip, which is disposed on a side of the encapsulation cover plate, and is configured to generate the respective partial size image of the imaging object; and
at least one optical element, which is disposed on a photosensitive side of the sensor chip, and is configured to receive part of incident light of the imaging object and image the part of the incident light on the sensor chip.

4. The image sensor of claim 3, wherein the at least one optical element is disposed between a film layer where the encapsulation cover plate is located and a film layer where the sensor chip is located; or
at least one optical element is disposed on a side of the encapsulation cover plate away from the sensor chip.

5. The image sensor of claim 3, wherein each of the plurality of sensor units further comprises: a coating disposed on each of at least one side surface of the encapsulation cover plate, wherein an opening is formed in the coating;
wherein an overlapping area exists between a vertical projection of the opening on a plane where the encapsulation cover plate is located and a vertical projection of the at least one optical element on the plane where the encapsulation cover plate is located.

6. The image sensor of claim 3, wherein each of the plurality of sensor units further comprises a shim, wherein the shim is disposed between a film layer where the encapsulation cover plate is located and a film layer where the sensor chip is located.

7. The image sensor of claim 3, wherein each of the at least one optical element comprises at least one of a lens, an imaging aperture or a collimator.

8. A method for manufacturing an image sensor, comprising:
providing a base substrate;
forming a sensor unit array on the base substrate, wherein the sensor unit array comprises a plurality of sensor units, the plurality of sensor units are arranged in an array, each of the plurality of sensor units is configured to generate a respective partial size image of an imaging object, and each of the plurality of sensor units comprises at least one interconnection structure;
preparing, on the base substrate, an encapsulation layer wrapping the sensor unit array and exposing the at least one interconnection structure of each of the plurality of sensor units;
preparing, on a side of the encapsulation layer away from the base substrate, a rewiring layer electrically connected to the at least one interconnection structure; and
preparing, on a side of the rewiring layer away from the encapsulation layer, a circuit board electrically connected to the rewiring layer.

9. The method for manufacturing an image sensor of claim 8, wherein preparing, on the base substrate, the encapsulation layer wrapping the sensor unit array and exposing the at least one interconnection structure of each of the plurality of sensor units comprises:
preparing, on the base substrate, the encapsulation layer wrapping the sensor unit array; and
thinning the encapsulation layer to expose the at least one interconnection structure of each of the plurality of sensor units.

10. The method for manufacturing an image sensor of claim 8, further comprising:
stripping the base substrate.

11. An image recognition method, adopting the image sensor of claim 1, and comprising:
acquiring a plurality of partial size recognition images generated by the sensor unit array;
acquiring, based on the plurality of partial size recognition images, position information of at least two image feature points; and
adopting, according to the position information of the at least two image feature points, an image feature point recognition algorithm to recognize a recognition image captured by the image sensor.

12. The image recognition method of claim 11, wherein adopting, according to the position information of the at least two image feature points, the image feature point recognition algorithm to recognize the recognition image captured by the image sensor comprises:
calculating, according to the position information of the at least two image feature points, a distance between any two image feature points of the at least two image feature points; and
adopting, according to the distance between the any two image feature points, the image feature point recognition algorithm to recognize the recognition image captured by the image sensor.

13. The image recognition method of claim 11, before acquiring the plurality of partial size recognition images generated by the sensor unit array, further comprising:
acquiring a plurality of partial size entry images generated by the sensor unit array a plurality of times, and generating a partial size entry image library; and
adopting an image stitching algorithm to generate a complete size entry image according to the partial size entry image library.

14. An electronic device, comprising the image sensor of claim 1.
